(19) United States
(12) Patent Application Publication
(10) Pub. No.: US 2009/0027864 A1
(43) Pub. Date: Jan. 29, 2009

(54) Printed circuit board and manufacturing method thereof

(75) Inventors: Chung-Woo Cho, Suwon-si (KR); Jong-Jin Lee, Daejeon (KR); Soon-Jin Cho, Suwon-si (KR); Yong-Duk Lee, Cheongju-si (KR); Ki-Young Yoo, Suwon-si (KR); Woo-Young Lee, Busanjin-gu (KR); Chin-Kwan Kim, Daejeon (KR); Jong-Yong Kim, Daejeon (KR); Dong-Ju Jeon, Seoul (KR)

Correspondence Address: STAAS & HALSEY LLP, SUITE 700, 1201 NEW YORK AVENUE, N.W., WASHINGTON, DC, 20005, US

(73) Assignee: SAMSUNG ELECTRO-MECHANICS CO., LTD., Suwon (KR)

(21) Appl. No.: 12/007,687

(22) Filed: Jan. 14, 2008

(30) Foreign Application Priority Data
Jul. 26, 2007 (KR) 10-2007-0075185

(51) Int. Cl. H05K 1/00; H05K 3/00

(52) U.S. Cl. 361/767; 29/852

(57) ABSTRACT

A printed circuit board and a method of manufacturing the printed circuit board are disclosed. A printed circuit board, which includes an insulation layer, a circuit pattern formed on a surface of the insulation layer that includes at least one pad, and a solder resist which covers the circuit pattern, and in which an opening is formed that exposes a portion of a side and a surface of the pad, can ensure a sufficient amount of attachment area for the pads and the solder resist, to strengthen the adhesion of the pads. Also, the adhesion can be increased between the electronic components and the printed circuit board, and heat release characteristics can be improved.

### CROSS-REFERENCE TO RELATED APPLICATIONS

This application claims the benefit of Korean Patent Application No. 10-2007-0075185 filed with the Korean Intellectual Property Office on Jul. 26, 2007, the disclosure of which is incorporated herein by reference in its entirety.

### BACKGROUND

1. Technical Field

The present invention relates to a printed circuit board and a method of manufacturing the printed circuit board.

2. Description of the Related Art

With advances in the electronics industry, portable electronic products, including products for cell phones and DMB (digital multimedia broadcasting), are becoming smaller and more highly functionalized, which in turn is creating a demand for electronic components that are subminiature in size, highly integrated, multi-functionalized, and high in performance. According to the higher levels of integration of electronic components, the number of I/O (input/output) is increasing, so that there are demands for increased numbers of pads on a printed circuit board for mounting components, as well as for decreased pad sizes and finer pitches for the circuit patterns in the printed circuit board.

Such increased number of I/O and fine pitch of circuit patterns can become causes of short circuiting between circuits and improper contact. In particular, when mounting electronic components on a printed circuit board, the surface of the printed circuit board is exposed to remnant solder, which can create undesired contacts, or solder bridges. Therefore, the outermost layers of a printed circuit board are often covered with a solder resist, which protects the outermost circuit patterns from damage by external forces and oxidation by air, and which prevents solder from attaching to unnecessary portions when mounting electronic components. The solder resist can cover the remaining portions other than the vicinity of the pads for mounting components on the printed circuit board.

FIG. 1 is a plan view illustrating a pad of a printed circuit board according to prior art, and FIG. 2 is a cross-sectional view across line A-A′ of FIG. 1. Referring to FIGS. 1 and 2, a circuit pattern 106 including a pad 104 is formed on the surface of the insulation layer 102 forming a part of the printed circuit board, while the surface of the insulation layer and the circuit pattern 106 are covered, besides the pad 104 and its vicinity.

An opening is formed in the solder resist 108, with the pad 104, as well as the portion of the circuit pattern 106 connected to the pad 104 and portions of the surface of the insulation layer 102 adjacent to the pad 104, exposed to the exterior through the opening. A structure in which the pads 104 and portions of the insulation layer 102 are thus exposed is referred to as an NSMD (non-solder mask defined) structure. While the NSMD structure provides high reliability of contacts when mounting components and superb heat release characteristics, because the pads 104 are completely exposed to the exterior, there is a risk of contamination before the mounting of the components, as the portion of the insulation layer 102 and the pads 104 are completely exposed to the external environment. Also, since the attachment areas are small, there is a risk that the adhesion of the pads 104 will be weakened.

In particular, according to the current trends towards finer circuit patterns 106, the attachment areas between the pads 104 and the insulation layer 102 are becoming even smaller, so that insufficient adhesion may occur, resulting in the pads 104 being peeled off from the insulation layer 102.

### SUMMARY

An aspect of the invention is to provide a printed circuit board and a method of manufacturing the printed circuit board, in which a sufficient amount of attachment area is ensured for the pads and the solder resist, to strengthen the adhesion of the pads.

One aspect of the invention provides a printed circuit board that includes an insulation layer, a circuit pattern formed on a surface of the insulation layer that includes at least one pad, and a solder resist which covers the circuit pattern, and in which an opening is formed that exposes a portion of a side and a surface of the pad.

The solder resist can be made of a heat-resistant insulating resin.

The pad can be at least one of a bonding pad, flip chip bonding pad, and a solder ball pad.

Another aspect of the invention provides a method of manufacturing a printed circuit board, which includes providing a board having a circuit pattern formed on its surface that includes at least one pad, applying a solder resist on the board, forming an opening in the solder resist such that a portion of a side and a surface of the pad are exposed, and surface-treating the pad.

Applying the solder resist can include coating the board by spraying solder resist ink, and curing the solder resist ink.

Forming the opening may be performed by way of a laser drill.

The laser can include at least one of CO₂ laser and YAG laser.

With certain embodiments of the invention, a sufficient amount of attachment area can be ensured for the pads and the solder resist, to strengthen the adhesion of the pads. Also, the adhesion can be increased between the electronic components and the printed circuit board, and heat release characteristics can be improved.

Additional aspects and advantages of the present invention will be set forth in part in the description which follows, and in part will be obvious from the description, or may be learned by practice of the invention.

### BRIEF DESCRIPTION OF THE DRAWINGS

FIG. 1 is a plan view illustrating a pad of a printed circuit board according to prior art.

FIG. 2 is a cross-sectional view across line A-A′ of FIG. 1.

FIG. 3 is a plan view illustrating a pad of a printed circuit board according to an embodiment of the invention.

FIG. 4 is a cross-sectional view across line B-B′ of FIG. 3.

FIG. 5 is a plan view illustrating a pad of a printed circuit board according to another embodiment of the invention.

FIG. 6 is a cross-sectional view across line C-C′ of FIG. 5.

FIG. 7 is a flowchart illustrating a method of manufacturing a printed circuit board according to an embodiment of the invention.

FIG. 8A, FIG. 8B, FIG. 8C, and FIG. 8D are cross-sectional views representing a flow diagram of a method of manufacturing a printed circuit board according to an embodiment of the invention.

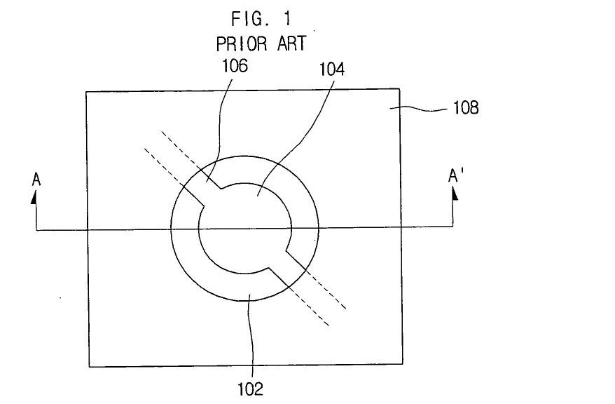

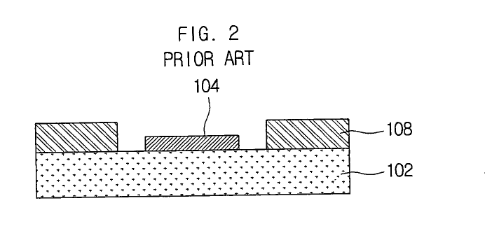

### DETAILED DESCRIPTION

As the invention allows for various changes and numerous embodiments, particular embodiments will be illustrated in drawings and described in detail in the written description. However, this is not intended to limit the present invention to particular modes of practice, and it is to be appreciated that all changes, equivalents, and substitutes that do not depart from the spirit and technical scope of the present invention are encompassed in the present invention. In the description of the present invention, certain detailed explanations of related art are omitted when it is deemed that they may unnecessarily obscure the essence of the invention.

While such terms as “first,” “second,” etc., may be used to describe various components, such components must not be limited to the above terms. The above terms are used only to distinguish one component from another.

The terms used in the present application are merely used to describe particular embodiments, and are not intended to limit the present invention. An expression used in the singular encompasses the expression of the plural, unless it has a clearly different meaning in the context. In the present application, it is to be understood that the terms such as “including” or “having,” etc., are intended to indicate the existence of the features, numbers, steps, actions, components, parts, or combinations thereof disclosed in the specification, and are not intended to preclude the possibility that one or more other features, numbers, steps, actions, components, parts, or combinations thereof may exist or may be added.

The printed circuit board and method of manufacturing the printed circuit board according to certain embodiments of the invention will be described below in more detail with reference to the accompanying drawings, in which those components are rendered the same reference numeral that are the same or are in correspondence, regardless of the figure number, and redundant explanations are omitted.

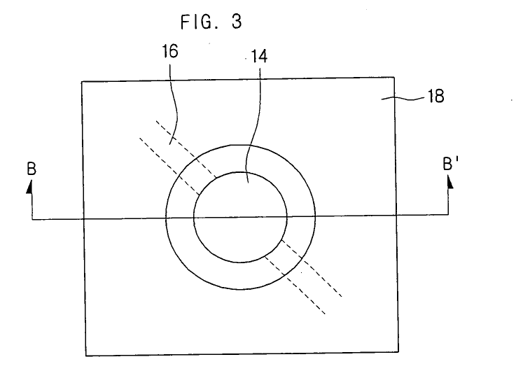

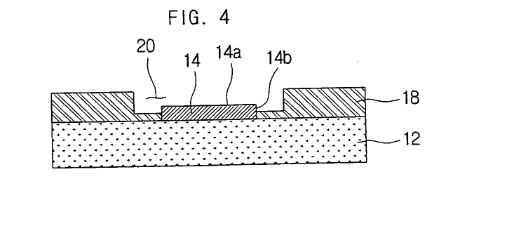

FIG. 3 is a plan view illustrating a pad of a printed circuit board according to an embodiment of the invention, and FIG. 4 is a cross-sectional view across line B-B′ of FIG. 3. In FIGS. 3 and 4 are illustrated an insulation layer 12, a pad 14, a surface 14a, a side 14b, a circuit pattern 16, a solder resist 18, and an opening 20.

The printed circuit board of this particular embodiment includes an insulation layer 12, a circuit pattern 16 which is formed on a surface of the insulation layer 12 and which includes a pad 14, and a solder resist 18, in which an opening 20 is formed that exposes the surface 14a and a portion of the side 14b of the pad 14, and which covers the circuit pattern 16. This arrangement ensures a sufficient amount of attachment area for the pad 14 and the solder resist 18, whereby the adhesion of the pad 14 can be strengthened. Furthermore, the adhesion between the electronic component and the printed circuit board can be increased, and heat release characteristics can be enhanced.

This particular embodiment presents a printed circuit board having a flip chip bonding pad 14, with which a component can be attached by flip chip bonding, or a solder ball pad 14, to which a solder ball can be attached. One opening 20 can be formed for each pad 14 such that the surface 14a and a portion of the side 14b of the pad 14 are exposed.

On the surface of the insulation layer 12, the circuit pattern 16 is formed, which includes at least one pad 14, and the surface of the insulation layer 12 on which the circuit pattern 16 is formed is covered by the solder resist 18. An opening 20 is formed in the solder resist 18 that exposes the surface 14a of the pad 14 and a portion of the side 14b of the pad 14. The opening 20 can be made larger than the size of the pad 14, to increase the attachment area for the I/O (input/output) terminals of an electronic component when mounting the component, and thus increase contact reliability. Also, as the surface 14a and a portion of the side 14b of the pad 14 are exposed to the external environment, the heat release properties can be enhanced.

An arrangement may also be conceived, for a multilayer printed circuit board having insulation layers 12 stacked in multiple layers, in which the solder resist 18 covers the outermost insulation layer 12.

The pad 14 is the location where the terminal of an electronic component mounted on the printed circuit board is to be attached. The solder resist 18 can cover portions other than the pads 14, to protect the circuit pattern 16 from the external environment.

Surface treatment can be performed on the pad 14, in order to prevent the pad 14 from oxidation and to provide high contact reliability and high conductivity for the component mounted by way of the pad 14. Any of a variety of surface treatment methods apparent to those skilled in the art can be used, such as HASL (hot air solder leveling), pre-flux coating, electroless nickel/gold plating, electroless palladium (Pd) plating, electroless silver (Ag) plating, electroless tin plating, etc.

The solder resist 18 can be a film that protects the insulation layer 12 and circuit pattern 16 from the exterior, and can prevent solder from attaching to unnecessary portions while mounting a component.

The recent trends towards finer pitch in circuit patterns 16 and increased number of I/O in electronic components can lead to problems of short circuiting between circuit pattern lines and improper contacts. To prevent such defects, the solder resist 18 may cover the regions except for the pads 14 on which the components will be mounted, to protect the circuit pattern 16 and insulation layer 12 from the exterior. The pads 14, however, need to be opened, in order to mount the components, and in this embodiment, an opening 20 is formed in the solder resist 18 such that the surface 14a and a portion of the side 14b of the pad 14 are exposed.

According to the higher levels of integration of current electronic components, the numbers of I/O are increasing, so that the number of pads 14 is increasing on the printed circuit board to which components are mounted, while the size of the pads 14 is decreasing. When the solder resist 18 is opened with the size of the pads 14 thus reduced, the attachment areas of the pads and insulation layer 12 can be too small, whereby defects may occur involving the pads 14 being peeled off from the insulation layer 12.

Thus, as illustrated in FIGS. 3 and 4, by forming the opening 20 of the solder resist 18 with a level difference such that the surface 14a and a portion of the side 14b of the pad 14 are exposed, the other surface of the pad 14 can be placed in surface contact with the insulation layer 12 and a portion of the side 14b of the pad 14 can be placed in surface contact with the solder resist 18, so that the attachment area can be increased and the adhesion of the pad 14 enhanced.

The opening 20 can be formed to be larger than the size of the pad 14, to broaden the attachment area of the pad 14 with respect to the exterior and thus facilitate heat release.

The height of the opening 20 in the solder resist 18 for exposing a portion of the side 14b can be determined in consideration of the adhesion to the pad 14.

The solder resist 18 can be made of a heat-resistant insulating resin. Resistance to heat may be desirable, in order that the solder resist 18 can satisfactorily withstand the melting temperature of the solder when mounting a component onto the printed circuit board, while an insulating quality may be desirable to prevent short circuiting between, adjacent circuit pattern lines.

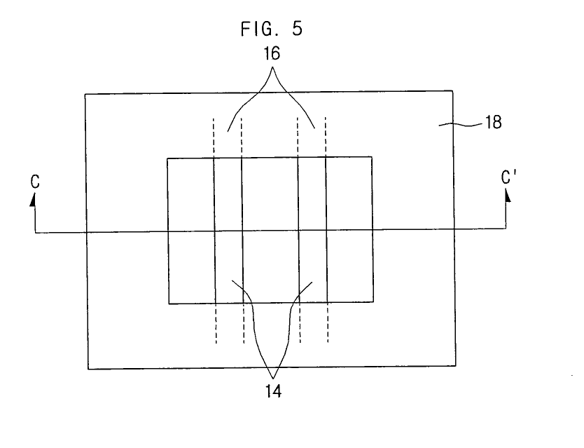

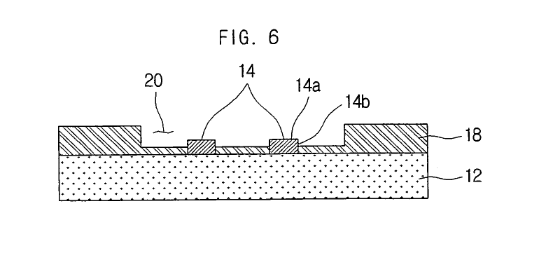

FIG. 5 is a plan view illustrating a pad of a printed circuit board according to another embodiment of the invention, and FIG. 6 is a cross-sectional view across line C-C′ of FIG. 5. In FIGS. 5 and 6 are illustrated an insulation layer 12, pads 14, surfaces 14a, sides 14b, a circuit pattern 16, a solder resist 18, and an opening 20.

In this particular embodiment, a printed circuit board is presented having wire bonding pads 14, by which a component can be attached to the printed circuit board by wire bonding.

In cases where the wire bonding pads 14 are formed continuously, it is possible to form an opening 20 with a level difference that exposes the surface 14a and a portion of the side 14b of the pad 14 individually for each of the pads 14 in the solder resist 18, but as illustrated in FIG. 6, it is also possible to form one opening 20 that exposes portions of the surfaces 14a and sides 14b of multiple pads 14. That is, the solder resist 18 between pads 14 can be removed to form a single opening 20.

As illustrated in FIGS. 5 and 6, this embodiment presents an arrangement in which one opening 20 is formed such that the surface 14a and a portion of the side 14b of each pad 14 are exposed for two pads 14.

The other elements are the same as those already set forth above, and thus will not be described in further detail.

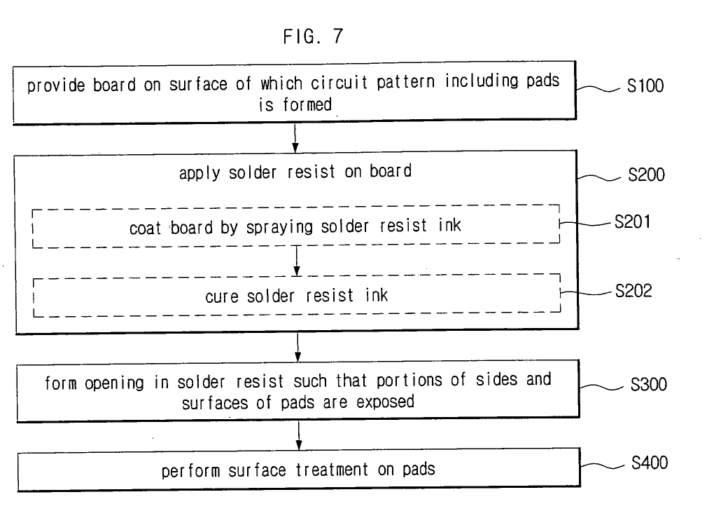

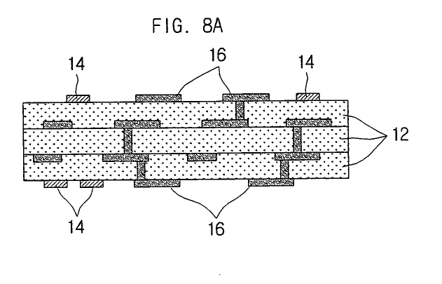

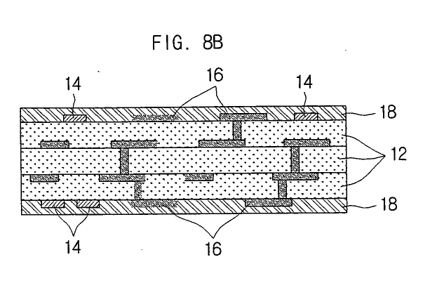

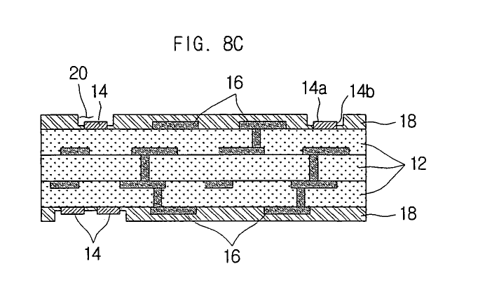

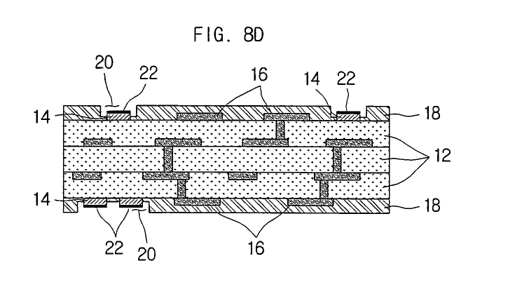

FIG. 7 is a flowchart illustrating a method of manufacturing a printed circuit board according to an embodiment of the invention, and FIGS. 8A to 8D are cross-sectional views representing a flow diagram of a method of manufacturing a printed circuit board according to an embodiment of the invention. In FIGS. 8A to 8D are illustrated insulation layers 12, pads 14, surfaces 14a, sides 14b, circuit patterns 16, solder resists 18, and openings 20.

The method of manufacturing a printed circuit board in this embodiment may include providing a board, on the surface of which a circuit pattern 16 including a pad 14 is formed, applying a solder resist 18 on the board, forming an opening 20 in the solder resist 18 such that the surface 14a and a portion of the side 14b of the pad are exposed, and surface-treating the pad 14, whereby a sufficient amount of attachment area is ensured for the pad 14 and the solder resist 18, and the adhesion of the pad 14 can be strengthened. Also, the adhesion between the component and the printed circuit board can be increased, and heat release characteristics can be enhanced.

In the method of manufacturing a printed circuit board according to this embodiment, first, as illustrated in FIG. 8A, a board can be provided, on a surface of which a circuit pattern 16 is formed that includes at least one pad 14 (S100).

The board on which the circuit pattern 16 is formed can be a multilayer printed circuit board that has multiple layers of insulation layers 12 stacked together. The pads 14 may be a part of the circuit patterns 16, and may be formed on the insulation layers 12 of the outermost layers to electrically connect the printed circuit board and the electronic components.

Next, as illustrated in FIG. 8B, a solder resist 18 can be applied on the board (S200). The solder resist 18 may be a membrane that protects the insulation layer 12 and circuit patterns 16 from the exterior, and may prevent solder from attaching to unnecessary portions while mounting components. The recent trends towards finer pitch in circuit patterns 16 and increased number of I/O in electronic components can lead to problems of short circuiting between circuit pattern lines and improper contacts. To prevent such defects, the solder resist 18 may cover the regions except for the pads 14 on which the components will be mounted, to protect the circuit pattern 16 and insulation layer 12 from the exterior.

A spray coating technique can be used as a method of applying the solder resist 18 on the board. This can include spraying solder resist ink onto the surfaces of the board to coat the board with solder resist ink (S201). The solder resist 18 can be made of a heat-resistant insulating resin, and can have a low viscosity if the solder resist ink is to be applied by way of spraying. However, the solder resist 18 can be applied onto the board by other methods, such as roller coating or curtain coating. The roller coating technique can include administering solder resist ink on at least one roller and forming the solder resist by rotating the roller on the board. The curtain coating technique can include ejecting a low-viscosity solder resist ink through at least one slit to form a curtain-like membrane, through which the board can be passed for coating.

When the solder resist ink is applied on the board, the solder resist ink may be cured (S202). Insufficient curing can cause the solder resist 18 film to be detached in subsequent processes, so the curing may be performed until a suitable degree of adhesion is obtained. Thermosetting type, UV-setting (ultraviolet-setting) type, or combined UV-thermosetting type solder resist ink can be used for the curing of the ink.

Next, as illustrated in FIG. 8C, an opening 20 can be formed in the solder resist 18 such that the surface 14a and a portion of the side 14b of the pad 14 are exposed (S300). According to the higher levels of integration of current electronic components, the numbers of I/O are increasing, so that the number of pads 14 is increasing on the printed circuit board to which components are mounted, while the size of the pads 14 is decreasing. When the solder resist 18 is opened with the size of the pads 14 thus reduced, the attachment areas of the pads and insulation layer 12 can be too small, whereby defects may occur involving the pads 14 being peeled off from the insulation layer 12.

Thus, as illustrated in FIG. 8C, by forming the opening 20 of the solder resist 18 with a level difference such that the surface 14a and a portion of the side 14b of the pad 14 are exposed, the other surface of the pad 14 can be placed in surface contact with the insulation layer 12 and a portion of the side 14b of the pad 14 can be placed in surface contact with the solder resist 18, so that the attachment area can be increased and the adhesion of the pad 14 enhanced.

Also, the opening 20 can be formed to be larger than the size of the pad 14, to broaden the attachment area of the pad 14 with respect to the exterior and thus facilitate heat release.

The height of the opening 20 in the solder resist 18 for exposing a portion of the side 14b can be determined in consideration of the adhesion to the pad 14.

The opening 20 can be formed to have a difference in level by way of a laser drill. In this case, at least one of CO₂ laser or YAG laser can be used for the laser. That is, the opening 20 can be processed using CO₂ laser or YAG laser by itself, or can be processed using both CO₂ laser and YAG laser in collaboration.

In cases where a laser drill is used to process the pads 14, the degree of drilling may vary according to the material being processed. That is, as the metal layer forming the pads 14 and the material forming the solder resist 18 are different, the degree of processing by the laser being used can be different accordingly. For example, in the case of using YAG laser, the processability of the metal layer made of copper (Cu) is known to be better than the processability of insulating resin. Therefore, when processing the pads 14 using a YAG laser drill, precision control may be necessary in order to avoid damage to the metal layer forming the pads 14. Also, two or more types of laser can be used in forming the openings 20, taking into consideration the processability of the material for the laser drills and selecting a suitable laser drill. For example, it may be possible to process the openings 20 with greater precision by using YAG laser to preliminarily process the solder resist 18 around the pads 14 and then using CO₂ laser to process the remaining portions.

The openings 20 can have the form of one opening 20 exposing portions of the surface 14a and the side 14b one pad 14 (for example, the form on the upper surface of the board illustrated in FIG. 8C) or the form of one opening 20 exposing portions of the surfaces 14a and sides 14b of several pads 14 (for example, the form on the lower surface of the board illustrated in FIG. 8C) in cases where the pads 14 are formed continuously.

Next, as illustrated in FIG. 8D, surface treatment can be performed on the exposed pads 14 (S400). The pad 14 is where the terminal of an electronic component mounted on the printed circuit board is to be attached. The solder resist 18 can cover portions other than the pads 14, to protect the circuit pattern 16 from the external environment.

Surface treatment can be performed on the pad 14, in order to prevent the pad 14 from oxidation and to provide high contact reliability and high conductivity for the component being mounted. Any of a variety of surface treatment methods apparent to those skilled in the art can be used, such as HASL (hot air solder leveling), pre-flux coating, electroless nickel/gold plating, electroless palladium (Pd) plating, electroless silver (Ag) plating, electroless tin plating, etc. This particular embodiment presents an arrangement in which surface treatment is performed on the pads 14 by applying electroless nickel/gold plating 22 on the surfaces of the pads 14.

While the spirit of the invention has been described in detail with reference to particular embodiments, the embodiments are for illustrative purposes only and do not limit the invention. It is to be appreciated that those skilled in the art can change or modify the embodiments without departing from the scope and spirit of the invention.

What is claimed is:

1. A printed circuit board comprising:
an insulation layer;
a circuit pattern formed on a surface of the insulation layer, the circuit pattern comprising a pad; and
a solder resist having an opening formed therein and covering the circuit pattern, the opening exposing a portion of a side and a surface of the pad.

2. The printed circuit board of claim 1, wherein the solder resist is made of a heat-resistant insulating resin.

3. The printed circuit board of claim 1, wherein the pad is at least one of a bonding pad, flip chip bonding pad, and a solder ball pad.

4. A method of manufacturing a printed circuit board, the method comprising:
providing a board having a circuit pattern formed on a surface thereof, the circuit pattern comprising a pad;
applying a solder resist on the board;
forming an opening in the solder resist such that a portion of a side and a surface of the pad are exposed; and
surface-treating the pad.

5. The method of claim 4, wherein the applying comprises:
coating the board by spraying solder resist ink; and
curing the solder resist ink.

6. The method of claim 4, wherein forming the opening is performed by way of a laser drill.

7. The method of claim 6, wherein the laser includes at least one of CO₂ laser and YAG laser.
